(19) United States
(12) Patent Application Publication
(10) Pub. No.: US 2009/0289930 A1
(43) Pub. Date: Nov. 26, 2009

(54) Operational amplifier circuit and display panel driving apparatus

(75) Inventor: Kouichi Nishimura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/461,056

(22) Filed: Jul. 30, 2009

(30) Foreign Application Priority Data
May 8, 2008 (JP) 201610/2008

(51) Int. Cl. G09G 5/00; H03F 3/45

(52) U.S. Cl. 345/211; 330/257; 330/253

(57) ABSTRACT

An operational amplifier circuit includes: an input stage for generating an internal current corresponding to a potential difference between inverting and non-inverting input terminals; and an output stage for driving an output terminal in response to the internal current. The output terminal includes: a floating current source through which the internal current flows; a PMOS transistor for driving the output terminal corresponding to a potential of a first terminal of the floating current source; and an NMOS transistor for driving the output terminal corresponding to a potential of a second terminal of the floating current source. The floating current source includes: a PMOS transistor whose source and drain are respectively connected to the first and second terminals; and an NMOS transistor whose drain and source are respectively connected to the first and second terminals. A back gate of the latter PMOS transistor is connected to the source thereof.

### BACKGROUND OF THE INVENTION

1. Field of the Invention

The present invention relates to an operational amplifier circuit and a display panel driving apparatus.

2. Description of the Related Art

There is a trend that display panels become larger and larger in size. In the field of television, particularly, liquid crystal display panels even exceeding 100 inches have emerged in the market, and this trend is considered to go on in the future.

One problem with a size increase of display panels is that the power consumption of amplifiers (operational amplifier circuits) included in driver ICs (integrated circuits) increases in conjunction with an increase in the capacity of each data line. In order to reduce the number of driver ICs per display panel, recent display devices tend to be equipped with driver ICs each providing a larger and larger number of outputs, and thereby require higher and higher power consumption per driver IC. This causes a problem that the temperature of the driver IC is raised during its operation.

One of approaches for taking measures against the rise in the temperature of the driver IC is to supply the driver IC with both of a power supply voltage V_{DD} and a power supply voltage V_{DD}/2 which is a half of the power supply voltage V_{DD}, and to operate amplifiers with the power supply voltage V_{DD}/2 if possible. Specifically, the driver IC operates in such a way that an amplifier capable of operating with a voltage in a range of V_{DD}/2 to V_{DD} is driven with a voltage in this range, and that an amplifier capable of operating with a voltage in a range of V_{SS} to V_{DD}/2 is driven with a voltage in this range. This approach makes it possible to reduce the power consumption of the amplifiers. This type of technique has been disclosed in Japanese Patent Application Publication No. Hei. 10-31200.

FIG. 1 is a diagram showing an example of a configuration of a data line driving circuit (i.e., a circuit part for outputting a driving voltage to a data line) in the driver IC employing such an approach. A positive-side amplifier 101 and a negative-side amplifier 102 receive inverting inputs from their respective outputs, and thereby operate as voltage followers. The positive-side amplifier 101 has a positive-side power supply terminal connected to a power supply line 103 through which the power supply voltage V_{DD} is supplied, and a negative-side power supply terminal connected to a power supply line 104 through which a power supply voltage V_{DD}/2 is supplied. On the other hand, the negative-side amplifier 102 has a positive-side power supply terminal connected to the power supply line 104 through which the power supply voltage V_{DD}/2 is supplied, and a negative-side power supply terminal connected to a ground line 105 through which a ground voltage V_{SS} is supplied.

For the purpose of eliminating a restriction on the input voltage ranges, it is desirable to use an amplifier having a rail-to-rail configuration for each of the positive-side amplifier 101 and the negative-side amplifier 102 shown in FIG. 1. When the rail-to-rail configuration is employed, the input voltage range of the positive-side amplifier 101 covers almost the entire voltage range of V_{DD}/2 to V_{DD}, and the input voltage range of the negative-side amplifier 102 covers almost the entire voltage range of V_{SS} to V_{DD}/2. This satisfies the requirement for the operation of the data line driving circuit.

FIG. 2 is a circuit diagram showing a typical configuration of a rail-to-rail amplifier. The configuration of the amplifier shown in FIG. 2 has been disclosed in the U.S. Pat. No. 5,311,145, for example. The amplifier shown in FIG. 2 includes an input stage 111 and an output stage 112.

The input stage 111 includes PMOS transistors MP₁ to MP₈ and NMOS transistors MN₁ to MN₈. The NMOS transistors MN₁ and MN₂ are respectively connected to an inverting input terminal In⁻ and a non-inverting input terminal In⁺, and thus constitute a differential transistor pair. Similarly, the PMOS transistors MP₁ and MP₂ are respectively connected to the inverting input terminal In⁻ and the non-inverting input terminal In⁺, and thus constitute another differential transistor pair. The PMOS transistor MP₃ has a gate supplied with a bias voltage BP1, and thus operates as a constant current source. Similarly, the NMOS transistor MN₃ has a gate supplied with a bias voltage BN1, and thus operates as another constant current source. The gates of the PMOS transistors MP₆, MP₇ are supplied with a bias voltage BP2, and thus the PMOS transistors MP₄ to MP₇ operate as a cascode current mirror. Similarly, the gates of the NMOS transistors MN₆, MN₇ are supplied with a bias voltage BN2, and thus the NMOS transistor MN₄ to MN₇ operate as another cascode current mirror. The gate of the PMOS transistor MP₈ is supplied with a bias voltage BP3, whereas the gate of the NMOS transistor MN₈ is supplied with a bias voltage BN3. Thereby, the PMOS transistor MP₈ and the NMOS transistor MN₈ operate as a floating current source. The thus-configured input stage 111 generates an internal current I_{IN}⁺ corresponding to the difference between the voltage applied to the inverting input terminal In⁻ and the voltage applied to the non-inverting input terminal In⁺, and thus outputs the internal current I_{IN}⁺ to the output stage 112.

The output stage 112 includes PMOS transistors MP₉, MP₁₀ and NMOS transistors MN₉, MN₁₀. The gate of the PMOS transistor MP₉ is supplied with the bias voltage BP3, whereas the gate of the NMOS transistor MN₉ is supplied with the bias voltage BN3. Thereby, the PMOS transistor MP₉ and the NMOS transistor MN₉ operate as another floating current source. The floating current source formed of the PMOS transistor MP₉ and the NMOS transistor MN₉ play a role of driving nodes N1, N2 at voltage levels corresponding to the internal current I_{IN}⁺. The gate of the PMOS transistor MP₁₀ is connected to the node N1, whereas the gate of the NMOS transistor MN₁₀ is connected to the node N2. The PMOS transistor MP₁₀ and the NMOS transistor MN₁₀ drive an output terminal Out at the voltage levels of the nodes N1, N2, respectively. Thereby, an output voltage is outputted from the output terminal Out. In a case where the amplifier shown in FIG. 2 is operated as a voltage follower, the output terminal Out is connected to the inverting input terminal In⁻. Thereby, the output voltage having the same voltage level as the input voltage inputted to the non-inverting input terminal In⁺ is outputted from the amplifier shown in FIG. 2.

When the amplifier shown in FIG. 2 is used as the positive-side amplifier 101, the power supply voltage V_{DD} is supplied through a positive-side power supply line 113, whereas the power supply voltage V_{DD}/2 is supplied through a negative-side power supply line 114. On the other hand, when the amplifier shown in FIG. 2 is used as the negative-side amplifier 102, the power supply voltage V_{DD}/2 is supplied through the positive-side power supply line 113, whereas the ground voltage V_{SS} is supplied through the negative-side power supply line 114.

Furthermore, a circuit in which the operational amplifier circuit shown in FIG. 2 additionally includes a circuit for cancelling an offset voltage has been disclosed in Japanese Patent Application Publication No. 2006-319921.

However, the use of the amplifier shown in FIG. 2 as the positive-side amplifier 101 or the negative-side amplifier 102 shown in FIG. 1 causes a problem that the amplifier does not operate when the power supply voltage V_{DD} is low. This is because the use of a low power supply voltage V_{DD} does not ensure a voltage high enough to normally operate the floating current source in the output stage 112 (the floating current source formed of the PMOS transistor MP₉ and the NMOS transistor MN₉), in particular.

Against this background, it is desired to provide an operational amplifier circuit capable of operating with less power consumption and lower power supply voltage, and a display panel driving apparatus employing the operational amplifier circuit.

### SUMMARY OF THE INVENTION

A first aspect of the present invention is an operational amplifier circuit including: an input stage which generates an internal current corresponding to a potential difference between an inverting input terminal and a non-inverting input terminal; and an output stage which drives an output terminal corresponding to the internal current. The output stage includes: a floating current source through which the internal current flows; a first output transistor which drives the output terminal corresponding to a potential of a first terminal of the floating current source; and a second output transistor which drives the output terminal corresponding to a potential of a second terminal of the floating current source. The floating current source includes: a PMOS transistor whose source and drain are respectively connected to the first and second terminals; and an NMOS transistor whose drain and source are respectively connected to the first and second terminals. In at least one of the first PMOS transistor and the first NMOS transistor, a back gate is connected to a source.

The operational amplifier circuit thus configured can reduce a voltage needed to operate the floating current source, and thus carry out its low-voltage operation. That is because the back gate is connected to the source in at least one of the PMOS transistor and the NMOS transistor constituting the floating current source.

The foregoing configuration is effective particularly for the operational amplifier circuit where the input stage operates by receiving a power supply voltage and a ground voltage, and the first output transistor and the second output transistor are connected together between a ground line through which the ground voltage is supplied and a power supply line through which an intermediate power supply voltage that is lower than the power supply voltage and higher than the ground voltage is supplied. The operation of the first and second output transistors by being supplied with the intermediate power supply voltage and the ground voltage is effective in reducing the power consumption of the operational amplifier circuit, whereas this operation makes it difficult to operate the floating current source. However, this problem can be avoided by connecting the back gate to the source in the PMOS transistor constituting the floating current source.

The foregoing configuration is also effective for the operational amplifier circuit in which the first and second output transistors are connected together between a power supply line through which the power supply voltage is supplied and the power supply line through which the intermediate power supply voltage is supplied. The operation of the first and second output transistors by being supplied with the power supply voltage and the intermediate power supply voltage is effective in reducing the power consumption of the operational amplifier circuit, whereas this operation makes it difficult to operate the floating current source. However, this problem can be avoided by connecting the back gate to the source in the of the NMOS transistor constituting the floating current source.

Another aspect of the present invention is a display panel driving apparatus for generating a driving voltage for driving a display panel. The apparatus includes: a positive-side amplifier which generates a first driving voltage in a range between a power supply voltage and an intermediate power supply voltage that is a half of the power supply voltage; and a negative-side amplifier which generates a second driving voltage in a range between a ground voltage and the intermediate power supply voltage. Each of the positive-side amplifier and the negative-side amplifier includes: an input stage which generates an internal current corresponding to a potential difference between an input terminal and an output terminal; and an output stage which outputs the first or second driving voltage from the output terminal corresponding to the internal current. The output stage includes: a floating current source through which the internal current flows; a first output transistor which drives the output terminal corresponding to a potential of a first terminal of the floating current source; and a second output transistor which drives the output terminal corresponding to a potential of a second terminal of the floating current source. The floating current source includes: a PMOS transistor whose source and drain are respectively connected to the first and second terminals; and an NMOS transistor whose drain and source are respectively connected to the first and second terminals. In the PMOS transistor in the floating current source in the output stage of the positive-side amplifier, a back gate is connected to the source. In the NMOS transistor in the floating current source in the output stage of the negative-side amplifier, a back gate is connected to the source.

Yet another aspect of the present invention is a display panel driving apparatus for generating a driving voltage for driving a display panel. The apparatus includes: a grayscale voltage supplying circuit which supplies multiple grayscale voltages; a D/A converter which selects one of the multiple grayscale voltages depending on image data; and an amplifier which generates a driving voltage corresponding to the selected grayscale voltage. The grayscale voltage supplying circuit includes: a positive-side γ amplifier which generates a positive-side bias voltage in a range between a power supply voltage and an intermediate power supply voltage that is a half of the power supply voltage; a negative-side γ amplifier which generates a negative-side bias voltage in a range between the intermediate power supply voltage and a ground voltage; and a ladder resistor which generates the grayscale voltages through voltage division upon receipt of the positive-side bias voltage and the negative-side bias voltage. Each of the positive-side γ amplifier and the negative-side γ amplifier includes: an input stage which generates an internal current corresponding to a potential difference between an input terminal and an output terminal; and an output stage which outputs the positive-side bias voltage or the negative-side bias voltage from the output terminal in response to the internal current. The output stage includes: a floating current source through which the internal current flows; a first output transistor which drives the output terminal corresponding to a potential of a first terminal of the floating current source; and a second output transistor which drives the output terminal corresponding to a potential of a second terminal of the floating current source. The floating current source includes: a PMOS transistor whose source and drain are respectively connected to the first and second terminals; an NMOS transistor whose drain and source are respectively connected to the first and second terminals. In the PMOS transistor in the floating current source in the output stage of the positive-side γ amplifier, a back gate is connected to the source. In the NMOS transistor in the floating current source in the output stage of the negative-side γ amplifier, a back gate is connected to the source.

The present invention provides an operational amplifier circuit and a display panel driving apparatus which are capable of operating with less power consumption and lower voltage.

### BRIEF DESCRIPTION OF THE DRAWINGS

FIG. 1 is a circuit diagram showing a configuration of a typical data line driving circuit.

FIG. 2 is a circuit diagram showing a configuration of a typical operational amplifier circuit.

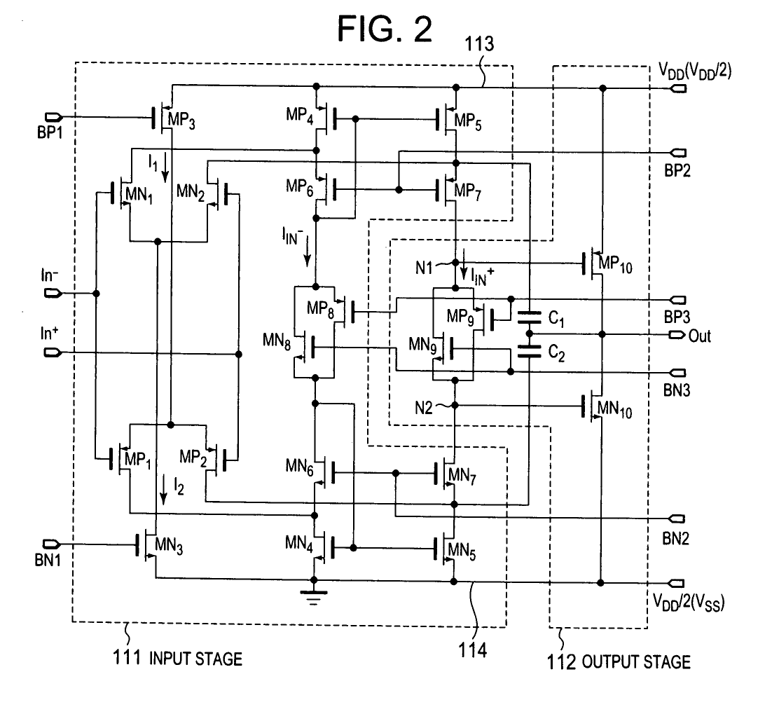

FIG. 3 is a circuit diagram showing a configuration of an operational amplifier circuit according to a first embodiment of the present invention.

FIG. 4 is a circuit diagram showing a configuration of the operational amplifier circuit according to the first embodiment additionally including offset cancellation circuits.

FIG. 5 is a circuit diagram showing a configuration of an operational amplifier circuit according to a second embodiment of the present invention.

FIG. 6 is a circuit diagram showing a configuration of the operational amplifier circuit according to the second embodiment additionally including offset cancellation circuits.

FIG. 7 is a circuit diagram showing a configuration of an operational amplifier circuit according to a third embodiment of the present invention.

FIG. 8 is a block diagram showing a configuration of a liquid crystal display panel driving circuit according to an embodiment of the present invention.

FIG. 9 is a conceptual diagram showing a range of a voltage outputted from the liquid crystal display panel driving circuit shown in FIG. 8.

FIG. 10 is a circuit diagram showing a preferable configuration of a grayscale voltage generating circuit of the liquid crystal display panel driving circuit shown in FIG. 8.

### DETAILED DESCRIPTION OF THE PREFERRED EMBODIMENTS

### First Embodiment

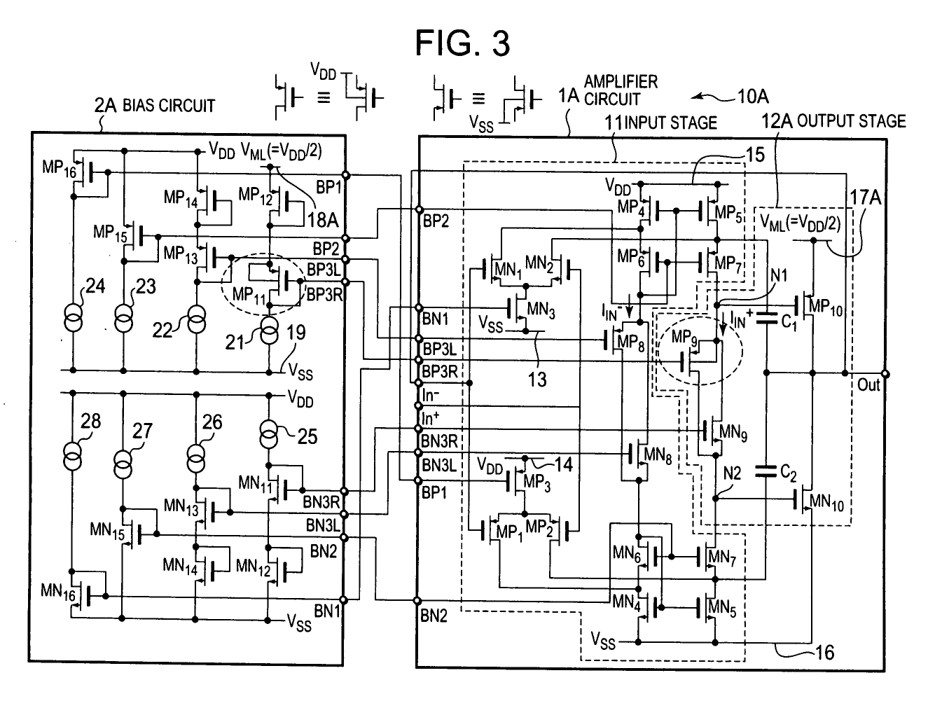

FIG. 3 is a circuit diagram showing the configuration of an operational amplifier circuit 10A according to a first embodiment of the present invention. The operational amplifier circuit 10A according to the first embodiment includes an amplifier circuit 1A and a bias circuit 2A for supplying a bias voltage to the amplifier circuit 1A. The amplifier circuit 1A includes an input stage 11 and an output stage 12A.

The input stage 11 is a circuit part for generating an internal current In⁺ corresponding to a potential difference between an inverting input terminal In⁻ and a non-inverting input terminal In⁺, and for supplying the internal current I_{In+} to the output stage. The input stage 11 includes PMOS transistors MP₁ to MP₈ and NMOS transistors MN₁ to MN₈. The back gates of the PMOS transistors MP₁ to MP₈ are biased to the power supply voltage V_{DD}, whereas the back gates of the NMOS transistors MN₁ to MN₈ are biased to the ground voltage V_{SS}.

The gates of the NMOS transistors MN₁, MN₂ are connected to the inverting input terminal In⁻ and the non-inverting input terminal In⁺, respectively. The sources of the NMOS transistors MN₁, MN₂ are commonly connected together. Thereby, the NMOS transistors MN₁, MN₂ constitute a differential transistor pair. The sources of the NMOS transistors MN₁, MN₂ are connected to the drain of the NMOS transistor MN₃. A bias voltage BN1 is supplied to the gate of the NMOS transistor MN₃. Thus, the NMOS transistor MN₃ operates as a constant current source for supplying a constant current to the differential transistor pair formed of the NMOS transistors MN₁, MN₂. The source of the NMOS transistor MN₃ is connected to a ground line 13 through which a ground voltage V_{SS} is supplied.

Similarly, the gates of the PMOS transistors MP₁, MP₂ are connected to the inverting input terminal In⁻ and the non-inverting input terminal In⁺, respectively. The sources of the PMOS transistors MP₁, MP₂ are commonly connected together. Thereby, the PMOS transistors MP₁, MP₂ constitute the other differential transistor pair. The sources of the PMOS transistors MP₁, MP₂ are connected to the drain of the PMOS transistor MP₃. A bias voltage BP1 is supplied to the gate of the PMOS transistor MP₃. Thus, the PMOS transistor MP₃ operates as a constant current source for supplying a constant current to the differential transistor pair formed of the PMOS transistors MP₁, MP₂. The source of the PMOS transistor MP₃ is connected to a power supply line 14 through which a power supply voltage V_{DD} is supplied.

The PMOS transistors MP₄ to MP₈ and the NMOS transistors MN₄ to MN₈ operate as an adding circuit for generating the internal current I_{IN}⁺ and an internal current I_{IN}⁻. The internal current I_{IN}⁺ corresponds to the sum of currents flowing through the NMOS transistor MN₂ and the PMOS transistor MP₂ of their respective differential transistor pairs, whereas the internal current I_{IN}⁻ corresponds to the sum of currents flowing through the NMOS transistor MN₁ and the PMOS transistor MP₁ of their respective differential transistor pairs.

Specifically, the PMOS transistors MP₄ to MP₇ constitute a current mirror (concretely, a cascode current mirror). The sources of the PMOS transistors MP₄, MP₅ are connected to a power supply line 15. The drains of the PMOS transistors MP₄, MP₅ are connected to the sources of the PMOS transistors MP₆, MP₇, respectively. Further, the drains of the PMOS transistors MP₄, MP₅ are respectively connected to the drains of the NMOS transistors MN₁, MN₂ constituting the former differential transistor pair. The gates of the PMOS transistors MP₄, MP₅ are commonly connected together, and are further connected to the drain of the PMOS transistor MP₆. The gates of the PMOS transistors MP₆, MP₇ are commonly connected together. A bias voltage BP2 for operating the current mirror is supplied to the gates of the PMOS transistors MP₆, MP₇.

Similarly, the NMOS transistors MN₄ to MN₇ constitute the other current mirror (concretely, a cascode current mirror). The sources of the NMOS transistors MN₄, MN₅ are connected to a ground line 16. The drains of the NMOS transistors MN₄, MN₅ are connected to the sources of the NMOS transistors MN₆, MN₇, respectively. Further, the drains of the NMOS transistors MN₄, MN₅ are respectively connected to the drains of the PMOS transistors MP₁, MP₂ constituting the latter differential transistor pair. The gates of the NMOS transistors MN₄, MN₅ are commonly connected together, and are further connected to the drain of the NMOS transistor MN₆. The gates of the NMOS transistors MN₆, MN₇ are commonly connected together. A bias voltage BN2 for operating the current mirror is supplied to the gates of the NMOS transistors MN₆, MN₇.

The source and drain of the PMOS transistor MP₈ are respectively connected to the drain and source of the NMOS transistor MP₈. Thereby, the PMOS transistor MP₈ and the NMOS transistor MN₈ operate as a “floating current source.” One end of a current source formed of general transistors is connected to a power supply terminal or a ground terminal. On the contrary, the two ends of this floating current source are floating, and can be accordingly connected to any places, respectively. A current feedback whose gain is “1” is locally applied to connection nodes between the PMOS transistor MP₈ and the NMOS transistor MN₈. Because of this feedback effect, a common connection node between the source of the PMOS transistor MP₈ and the drain of the NMOS transistor MN₈ as well as a common connection node between the drain of the PMOS transistor MP₈ and the source of the NMOS transistor MN₈ have a high impedance. From this, too, it is understood that the PMOS transistor MP₈ and the NMOS transistor MN₈ constitute the floating current source. The floating current source formed of the PMOS transistor MP₈ and the NMOS transistor MN₈ is connected between the drain of the PMOS transistor MP₆ and the drain of the NMOS transistor MN₆. Bias voltages BP3L, BN3L for operating the floating current source are supplied to the gates of the PMOS transistor MP₈ and the NMOS transistor MN₈, respectively.

Internal currents I_{IN}⁺, I_{IN}⁻ are generated by the two current mirrors and the floating current source. The internal current I_{IN}⁺ thus generated is supplied to the output stage 12A. The sum of the current flowing through the NMOS transistor MN₂ and the current flowing through the PMOS transistor MP₂ corresponds to the potential difference between the inverting input terminal In⁻ and the non-inverting input terminal In⁺. As a result, generated is the internal current I_{IN}⁺ corresponding to the potential difference between the inverting input terminal In⁻ and the non-inverting input terminal In⁺.

In this embodiment, the input stage 11 is configured to operate by receiving the power supply voltage V_{DD} and the ground voltage V_{SS}. Because the input stage has a rail-to-rail configuration, the range of a voltage inputted to the input stage 11 is not lower than the ground voltage V_{SS} and not higher than the power supply voltage V_{DD}.

The output stage 12A is a circuit part for driving an output terminal Out in response to the internal current I_{IN}⁺ supplied from the input stage 11. The output stage 12A includes PMOS transistors MP₉, MP₁₀, NMOS transistors MN₉, MN₁₀, and capacitors C₁, C₂.

The source and drain of the PMOS transistor MP₉ are connected to the drain and source of the NMOS transistor MN₉, respectively. Thereby, the PMOS transistor MP₉ and the NMOS transistor MN₉ operate as a “floating current source” as described above. The floating current source formed of the PMOS transistor MP₉ and the NMOS transistor MN₉ is connected between the drain of the PMOS transistor MP₇ and the drain of the NMOS transistor MN₇. Bias voltages BP3R, BN3R for operating the floating current source are supplied to the gates of the PMOS transistor MP₉ and the NMOS transistor MN₉, respectively.

The back gate of the PMOS transistor MP₉ is connected to the source thereof. In other words, the back gate of the PMOS transistor MP₉ is biased to the potential of the source thereof. This is one of the characteristics of the amplifier circuit 1A according to this embodiment. As described later, the connection of the back gate of the PMOS transistor MP₉ to the source thereof is important for the amplifier circuit 1A to carry out its low-voltage operation.

The PMOS transistor MP₁₀ and the NMOS transistor MN₁₀ operate as output transistors for driving the output terminal Out corresponding to the potentials of the two ends (i.e., nodes N1, N2) of the floating current source formed of the PMOS transistor MP₉ and the NMOS transistor MN₉. Specifically, the source of the PMOS transistor MP₁₀ is connected to a power supply line 17A through which an intermediate power supply voltage V_{ML} is supplied, the drain of the PMOS transistor MP₁₀ is connected to the output terminal Out, and the gate of the PMOS transistor MP₁₀ is connected to the node N1. Here, the intermediate power supply voltage V_{ML} is a voltage which is higher than the ground voltage V_{SS} and lower than the power supply voltage V_{DD}. In this embodiment, the intermediate power supply voltage V_{ML} is a voltage V_{DD}/2 which is a half of the power supply voltage V_{DD}. The back gate of the PMOS transistor MP₁₀ is biased to the power supply voltage V_{DD}. On the other hand, the source of the NMOS transistor MN₁₀ is connected to a ground line 16 through which the ground voltage V_{SS} is supplied, the drain of the NMOS transistor MN₁₀ is connected to the output terminal Out, and the gate of the NMOS transistor MN₁₀ is connected to the node N2. The back gate of the NMOS transistor MN₁₀ is biased to the ground voltage V_{SS}. This connecting method of the PMOS transistor MP₁₀ and the NMOS transistor MN₁₀ makes the potential of the output terminal Out determined by the potentials of the nodes N1, N2.

It should be noted that the output stage 12A operates by receiving the intermediate power supply voltage V_{ML} and the ground voltage V_{SS}. As described later, the operation of the output stage 12A by receiving the intermediate power supply voltage V_{ML} which is lower than the power supply voltage V_{DD} is important in reducing the power consumption.

In the circuit shown in FIG. 3, the output terminal Out of the amplifier circuit 1A is connected to the inverting input terminal In⁻. Thus, the amplifier circuit 1A operates as a voltage follower for outputting an output voltage having the same level as the input voltage inputted to the non-inverting input terminal In⁺.

The bias circuit 2A is a circuit for supplying the bias voltages BP1, BP2, BP3R, BP3L, BN1, BN2, BN3R, BN3L to the amplifier circuit 1A. The bias circuit 2A includes PMOS transistors MP₁, to MP₁₆, NMOS transistors MN₁, to MN₁₆ and current sources 21 to 28. Each of the PMOS transistors MP₁, to MP₁₆ and the NMOS transistors MN₁₁, to MN₁₆ is diode-connected. The PMOS transistors MP₁₁, MP₁₂ and the current source 21 are a circuit part for generating the bias voltage BP3R. The PMOS transistors MP₁₃, MP₁₄ and the current source 22 are a circuit part for generating the bias voltage BP3L. The PMOS transistor MP₁₅ and the current source 23 are a circuit part for generating the bias voltage BP2. The PMOS transistor MP₁₆ and the current source 24 are a circuit part for generating the bias voltage BP1. In addition, the NMOS transistors MN₁₁, MN₁₂ and the current source 25 are a circuit part for generating the bias voltage BN3R. The NMOS transistors MN₁₃, MN₁₄ and the current source 26 are a circuit part for generating the bias voltage BN3L. The NMOS transistor MN₁₅ and the current source 27 are a circuit part for generating the bias voltage BN2. The NMOS transistor MN₁₆ and the current source 28 are a circuit part for generating the bias voltage BN1.

In the bias circuit 2A, the circuit part for generating the bias voltage BP3R is configured in such a way as to operate by receiving the intermediate power supply voltage V_{ML} which is lower than the power supply voltage V_{DD}. Specifically, the PMOS transistors MP₁, MP₁₂ and the current source 21 are connected between a ground line 19 and a power supply line 18A through which the intermediate power supply voltage V_{ML} is supplied. The drain of the PMOS transistor MP₁₁ is connected to its own gate, and the drain of the PMOS transistor MP₁₂ is connected to its own gate. The bias voltage BP3R is outputted from the gate of the PMOS transistor MP₁₁. As described later, the operation of the PMOS transistors MP₁₁, MP₁₂ and the current source 21 by receiving the intermediate power supply voltage V_{ML} lower than the power supply voltage V_{DD} is important in reducing the power consumption of this circuit part.

The back gate of the PMOS transistor MP₁₁ is connected to the source thereof. In other words, the back gate of PMOS transistor MP₁₁ is biased to the potential of the source thereof. As described later, this is important for enabling the PMOS transistors MP₁₁, MP₁₂ and the current source 21 to operate by receiving the intermediate power supply voltage V_{ML} lower than the power supply voltage V_{DD}.

On the other hand, the back gates of the PMOS transistors MP₁₂ to MP₁₆ are biased to the power supply voltage V_{DD}, whereas the back gates of the NMOS transistors MN₁₁ to MN₁₆ are biased to the ground voltage V_{SS}.

One of the characteristics of the operational amplifier circuit 10A shown in FIG. 3 is that the input stage 11 operates by receiving the power supply voltage V_{DD} and the ground voltage V_{SS} whereas the output stage 12A operates by receiving the intermediate power supply voltage V_{ML} and the ground voltage V_{SS}. Here, the intermediate power supply voltage V_{ML} is a voltage which is lower than the power supply voltage V_{DD} and higher than the ground voltage V_{SS}. The use of the intermediate power supply voltage V_{MH} makes it possible to reduce the power consumption of the output stage 12A. If the intermediate power supply voltage V_{ML} is the voltage V_{DD}/2 which is a half of the power supply voltage V_{DD}, the output stage 12A consumes only a half of the power which the output stage 12A would consume when being supplied with the power supply voltage V_{DD}. The power consumed by the input stage 11 is negligibly smaller than the power consumed by the output stage 12A even if the power supply voltage supplied to the input stage 11 is high, because the current flowing through the input stage 11 is small in amount. Accordingly, the influence of the power consumed by the input stage 11 on the overall power consumption is small. On the contrary, the current flowing through the output stage 12A is the sum of an idling current which is several times as large as the current flowing through the input stage 11 and the current flowing through the output load. Accordingly, the current flowing through the output stage 12A occupies approximately 80% of the overall amount of current consumed. For this reason, even if the power supply voltage is reduced in the output stage 12A only, the reduction brings about a large effect in reducing the power consumption.

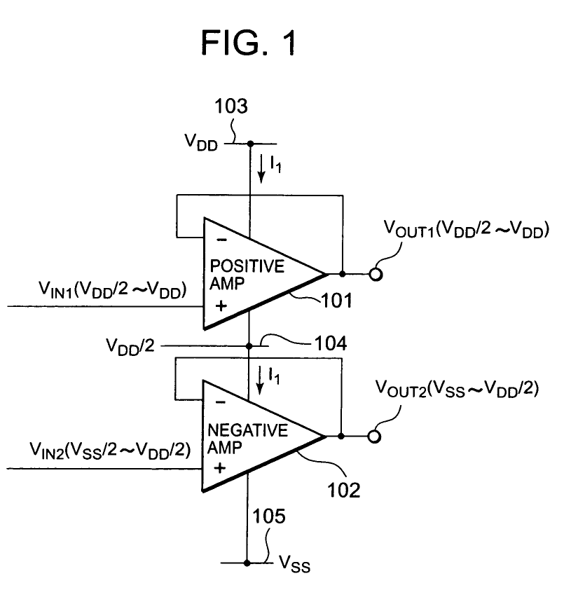

Because the output stage 12A is operated with the intermediate power supply voltage V_{ML} lower than the power supply voltage V_{DD}, the voltage outputted from the output stage 12A is limited to a range of V_{SS}+0.2V to V_{ML}−0.2V. However, this limitation does not matter to some applications. For example, in a case where the operational amplifier circuit shown in FIG. 3 is applied to a negative-side amplifier 102 shown in FIG. 1, if the voltage outputted from the output stage 12A is in the range of V_{SS}+0.2V to V_{DD}/2−0.2V, the output voltage is sufficient for the practical use. For this reason, the operational amplifier circuit 10A shown in FIG. 3 can be applied to the negative-side amplifier 102 shown in FIG. 1 by setting the intermediate power supply voltage V_{ML} to the voltage V_{DD}/2.

A problem with the operation of the output stage 12A with the intermediate power supply voltage V_{ML} lower than the power supply voltage V_{DD} is difficulty in ensuring a voltage large enough to operate the floating current source (the PMOS transistor MP₉ and the NMOS transistor MN₉) of the output stage 12A. This problem becomes more serious when the power supply voltage V_{DD} is reduced.

For the purpose of dealing with the problem with the voltage for operating the floating current source, the back gate of the PMOS transistor MP₉ is connected to the source thereof in the amplifier circuit 1A according to this embodiment. This makes it possible to operate the amplifier circuit 1A with a low voltage. The effectiveness of the connection of the back gate of the PMOS transistor MP₉ to the source thereof will be hereinbelow discussed.

While the operational amplifier circuit 10A shown in FIG. 3 is operating, a voltage V_{BP3R} between the gate of the PMOS transistor MP₉ receiving the bias voltage BP3R and the power supply line 17A through which the intermediate power supply voltage V_{ML} is supplied is equal to the sum of a voltage between the gate and source of the PMOS transistor MP₁₀ and a voltage between the gate and source of the PMOS transistor MP₉. Thus, the voltage V_{BP3R} is expressed by the following formula:

V_{BP3R}=V_{GS(MP10)}+V_{GS(MP9)} Formula (1)

where V_{GS(MP10)} denotes the voltage between the gate and source of the PMOS transistor MP₁₀, and V_{GS(MP9)} denotes the voltage between the gate and source of the PMOS transistor MP₉.

For operating the operational amplifier circuit 10A shown in FIG. 3, the sum of the voltage V_{BP3R} expressed with Formula (1) and the minimum operating voltage of the current source 21 (i.e., the saturation voltage V_{DS(sat)} between the drain and source of the transistor constituting the current source 21) should be lower than the intermediate power supply voltage V_{ML}. Specifically, the following condition needs to be satisfied.

V_{BP3R}+V_{DS(sat)}<V_{ML} Formula (2)

From Formula (2),

V_{BP3R}<V_{ML}−V_{DS(sat)} Formula (2′)

is obtained.

Here, a voltage V_{GS} between the gate and source of a MOS transistor is generally expressed with the following formula:

$$\begin{matrix}[ Mathematical Formula 1 ] & \\ {V}_{GS} = \sqrt{\frac{2 {I}_{D}}{β}} + {V}_{T 0} + γ \sqrt{{V}_{B}} & Formula ( 3 ) \\ where & \\ [ Mathematical Formula 2 ] & \\ β = \frac{W}{L} μ {C}_{0} & Formula ( 4 a ) \\ γ = \frac{\sqrt{2 {ɛ}_{0} {ɛ}_{S} {qN}_{A}}}{{C}_{0}} & Formula ( 4 b ) \\ and & \\ {C}_{0} = \frac{{ɛ}_{0} {ɛ}_{S}}{{t}_{0}} & Formula ( 4 c )\end{matrix}$$

where W denotes the gate width; L, the gate length; μ, a mobility; C₀, a capacitance of a gate oxide film per unit area; V_{TO}, a threshold voltage to be applied when a voltage between the back gate and source is 0V; V_{B}, a voltage between the back gate and source; ∈₀, the dielectric constant of a free space (8.86×10⁻¹² F/cm); ∈ₛ, the relative permittivity of a semiconductor (3.9); q, the amount of charge of an electron (1.6×10⁻² C); t₀, the thickness of the gate oxide film; and NA, an acceptor density. γ varies depending on the process of manufacturing the MOS transistor. An average value of γ is approximately 0.5.

Here, the voltage between the back gate and source of the PMOS transistor MP₉ is zero volts, because the back gate of the PMOS transistor MP₉ is connected to the source thereof. Specifically, for the PMOS transistor MP₉, the value representing the third term of Formula (3) is zero. Accordingly, in this embodiment, the voltage V_{GS(MP9)} between the gate and source of the PMOS transistor MP₉ is reduced. This makes it possible to satisfy the condition expressed with Formula (2′) even when the intermediate power supply voltage V_{ML} becomes lower in conjunction with the reduction in the power supply voltage V_{DD}. In other words, this embodiment enables the operational amplifier circuit 10A to carry out its low-voltage operation.

Another characteristic of the operational amplifier circuit 10A shown in FIG. 3 is that the intermediate power supply voltage V_{ML} which is lower than the power supply voltage V_{DD} is used to cause the bias circuit 2A to generate the bias voltage BP3R. This use enables the operational amplifier circuit 10A to effectively reduce the power consumption of the circuit part formed of the PMOS transistors MP₁₁, MP₁₂ and the current source 21.

Here, the foregoing discussion is the case with the PMOS transistors MP₁₁, MP₁₂ as well. Specifically, when the intermediate power supply voltage V_{ML} becomes lower, it becomes difficult to operate the PMOS transistors MP₁₁, MP₁₂ and the current source 21. For this reason, for the purpose of operating the PMOS transistors MP₁₁, MP₁₂ and the current source 21, the condition expressed with Formula (5) should be satisfied:

V_{GS(MP11)}+V_{GS(MP12)}+V_{DS(sat)}<V_{ML} Formula (5)

where V_{GS(MP11)} denotes the voltage between the gate and source of the PMOS transistor MP₁₁, and V_{GS(MP12)} denotes the voltage between the gate and source of the PMOS transistor MP₁₂. For the PMOS transistor MP₁₁, the value representing the third term of Formula (3) is zero because the back gate of the PMOS transistor MP₁₁ is connected to the source thereof in this embodiment. Accordingly, in this embodiment, the voltage V_{GS(MP11)} between the gate and source of the PMOS transistor MP₁, is reduced. This makes it possible to satisfy the condition expressed with Formula (5) even when the intermediate power supply voltage V_{ML} becomes lower (that is, even when the operational amplifier circuit 10A operates with the lower voltage). In other words, this embodiment enables the operational amplifier circuit 10A to carry out its low-voltage operation.

As described above, the operational amplifier circuit 10A of this embodiment can reduce its power consumption by causing the output stage 12A to operate by receiving the intermediate power supply voltage V_{ML} (which is lower than the power supply voltage V_{DD}). In addition, the operational amplifier circuit 10A realizes its low voltage operation because the back gate is connected to the source in the PMOS transistor MP₉ in the floating current source in the output stage 12A. Furthermore, the operational amplifier circuit 10A realizes its low voltage operation because the back gate is connected to the source in the PMOS transistor MP₁, used to generate the bias voltage BP3R.

The configuration of the operational amplifier circuit 10A shown in FIG. 3 is likely to increase an offset voltage in some cases. For this reason, the offset voltage needs to be dealt with depending on cases. In most cases, the offset voltage occurs in the operational amplifier circuit 10A shown in FIG. 3 due to the following four factors:
(A) difference between threshold voltages of the PMOS transistors MP₄, MP₅ constituting the active load of the current mirror;
(B) difference between threshold voltages of the NMOS transistors MN₄, MN₅ constituting the active load of the other current mirror;
(C) difference between threshold voltages of the NMOS transistors MN₁, MN₂ constituting the differential transistor pair; and
(D) difference between threshold voltages of the PMOS transistors MP₁, MP₂ constituting the other differential transistor pair.

Problems with the offset voltage can be solved, if these four factors are dealt with.

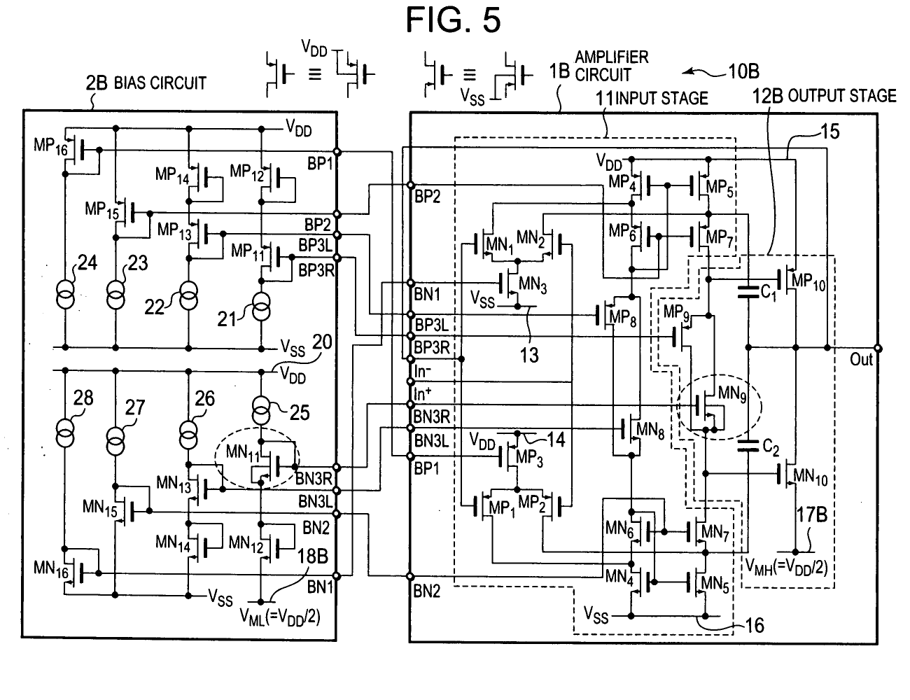

One of approaches for dealing with the occurrence of the offset voltage is to add an offset cancellation circuit to the amplifier circuit 1A. FIG. 5 is a circuit diagram showing the configuration of the amplifier circuit 1A to which the offset cancellation circuit is added. Note that, in FIG. 5, the NMOS transistor MN₃ shown in FIG. 3 is illustrated as a current source I₁; the PMOS transistor MP₃ shown in FIG. 3 is illustrated as a current source I₂; and the floating current source formed of the PMOS transistor MP₈ and the NMOS transistor MN₈ is illustrated as a current source I₃.

In the amplifier circuit 1A shown in FIG. 5, a switch SW1 is inserted between the drain of the PMOS transistor MP₄ and the sources of the PMOS transistors of MP₆, MP₇, as well as a switch SW2 is inserted between the drain of the PMOS transistor MP5 and the sources of the PMOS transistors MP₆, MP₇. The switches SW1, SW2 are make/break switches, and are configured in such a way that: the common terminal and the make terminal of each of the switches SW1, SW2 are electrically connected together once a control signal supplied to the switches SW1, SW2 are activated; the common terminal and the break terminal of each of the switches SW1, SW2 are electrically connected together once the control signal supplied to the switches SW1, SW2 are deactivated. The common terminal of the switch SW1 is connected to the drain of the PMOS transistor MP₄, the make terminal of the switch SW1 is connected to the source of the PMOS transistor MP₇, and the break terminal of the switch SW1 is connected to the source of the PMOS transistor MP₆. On the other hand, the common terminal of the switch SW2 is connected to the drain of the PMOS transistor MP₅, the make terminal of the switch SW2 is connected to the source of the PMOS transistor MP₆, and the break terminal of the switch SW2 is connected to the source of the PMOS transistor MP₇.

Similarly, a switch SW3 is inserted between the drain of the NMOS transistor MN₄ and the sources of the NMOS transistors MN₆, MN₇, as well as a switch SW4 is inserted between the drain of the NMOS transistor MN5 and the sources of the NMOS transistors MN₆, MN₇. The switches SW3, SW4 are make/break switches as well. The common terminal of the switch SW3 is connected to the drain of the NMOS transistor MN₄, the make terminal of the switch SW3 is connected to the source of the NMOS transistor MN₇, and the break terminal of the switch SW3 is connected to the source of the NMOS transistor MN₆. On the other hand, the common terminal of the switch SW4 is connected to the drain of the NMOS transistor MN₅, the make terminal of the switch SW4 is connected to the source of the NMOS transistor MN₆, and the break terminal of the switch SW4 is connected to the source of the NMOS transistor MN₇.

Furthermore, a switch SW5 is inserted between the non-inverting input terminal In⁺ and the two differential transistor pairs (i.e., the paired NMOS transistors MN₁, MN₂ and the paired PMOS transistors MP₁, MP₂) of the input stage 11, whereas a switch SW6 is inserted between the inverting input terminal In⁻ and the two differential transistor pairs of the input stage 11. The switches SW5, SW6 are make/break switches as well. The common terminal of the switch SW5 is connected to the non-inverting input terminal In⁺, the make terminal of the switch SW5 is connected to the gates of the NMOS transistor MN₁ and the PMOS transistor MP₁, and the break terminal of the switch SW5 is connected to the gates of the NMOS transistor MN2 and the PMOS transistor MP₂. On the other hand, the common terminal of the switch SW6 is connected to the inverting input terminal In⁻, the make terminal of the switch SW6 is connected to the gates of the NMOS transistor MN₂ and the PMOS transistor MP₂, and the break terminal of the switch SW6 is connected to the gates of the NMOS transistor MN₁ and the PMOS transistor MP₁.

All the switches SW1 to SW6 operate in linkage with one another. Possible conditions of the amplifier circuit 1A are the following two conditions. In a first condition (hereinafter referred to as a “make condition”)), the common and make terminals of each of the switches SW1 to SW6 are connected together. In a second condition (hereinafter referred to as a “break condition”), the common and break terminals of each of the switches SW1 to SW6 are connected together.

The switches SW1 to SW6 shown in FIG. 5 are switched between the two conditions at appropriate intervals together, so that the time-average offset voltage becomes zero. This makes it possible to substantially solve the problem with the offset voltage which occurs due to the above-mentioned four factors. Specifically, each time the switches SW1, SW2 are switched between the two conditions together, the connection of the PMOS transistor MP₄ is switched between the PMOS transistors MP₆ and MP₇ whereas the connection of the PMOS transistor MP₅ is reversely switched between the PMOS transistors MP₇ and MP₆. Thus, the polarity of the offset voltage which occurs due to the difference between the threshold voltages of the respective PMOS transistors MP₄, MP₅ (the offset voltage caused by the factor (A)) is reversed. In addition, each time the switches SW3, SW4 are switched between the two conditions together, the connection of the NMOS transistor MN₄ is switched between the NMOS transistor MN₆ and the NMOS transistor MN₇ whereas the connection of the NMOS transistor MN₅ is switched between the NMOS transistor MN₇ and the NMOS transistor MN₆. Thus, the polarity of the offset voltage which occurs due to the difference between the threshold voltages of the respective NMOS transistors MN₄, MN₅ (the offset voltage caused by the factor (B)) is reversed. Furthermore, each time the switches SW5, SW6 are switched between the two conditions together, the connection of the non-inverting input terminal In⁺ is switched between a set of the NMOS transistor MN₂ and the PMOS transistor MP₂, and a set of the NMOS transistor MN₁ and the PMOS transistor MP₁, whereas the connection of the inverting input terminal In⁻ is switched between a set of the NMOS transistor MN₁ and the PMOS transistor MP₁, and a set of the NMOS transistor MN₂ and the PMOS transistor MP₂, the paired NMOS transistors MN₁, MN₂ and the paired PMOS transistors MP₁, MP₂ constituting the differential transistor pairs. Thus, the polarity of the offset voltage which occurs due to the difference between the threshold voltages of the respective NMOS transistors MN₁, MN₂ and the difference between the threshold voltages of the respective PMOS transistors MP₁, MP₂ (the offset voltage caused by the factors (C), (D)) is reversed. Accordingly, a voltage V_{O} outputted from the output terminal Out is expressed with the following formula:

V_{O}=V_{IN}±V_{OS} Formula (6)

where V_{OS} denotes the offset voltage which occurs due to the four factors, and V_{IN} denotes an input voltage inputted into the non-inverting input terminal In⁺. When the amplifier circuit 1A is put in one of the make condition and the break condition, “+” is selected from the plus-minus sign“±.” When the amplifier circuit 1A is put in the other condition, “−” is selected therefrom. Thereby, the voltage V_{O} coincides with the voltage V_{IN} in a time-averaged manner by changing the switches SW1 to SW6 between the two conditions at appropriate intervals together. Thus, the problem with the offset voltage is solved.

For example, in a case where the amplifier circuit 1A shown in FIG. 3 is used as an amplifier for driving a data line of a liquid crystal display panel, the offset voltage of the amplifier can be recognized as a vertical stripe (a stripe extending in the direction of the data line) by the human eye. However, in a case where the amplifier circuit 1A shown in FIG. 5 is employed as the amplifier, it is possible to eliminate the vertical stripe which occurs due to the offset voltage of the amplifier by changing the switches SW1 to SW6 between the two conditions at appropriate intervals (for example, for each horizontal period or for each frame period) together.

### Second Embodiment

FIG. 5 is a circuit diagram showing the configuration of an operational amplifier circuit 10B according to a second embodiment of the present invention. The operational amplifier circuit 10B has the configuration similar to that of the operational amplifier circuit 10A shown in FIG. 3. The differences therebetween are as follows. First, in the operational amplifier circuit 10B shown in FIG. 5, an output stage 12B of an amplifier circuit 1B operates by receiving the power supply voltage V_{DD} and an intermediate power supply voltage V_{MH}. Specifically, the source of the PMOS transistor MP₁₀ is connected to a power supply line 15 through which the power supply voltage V_{DD} is supplied, whereas the source of the NMOS transistor MN₁₀ is connected to a power supply line 17B through which the intermediate power supply voltage V_{MH} is supplied. Here, the intermediate power supply voltage V_{MH} is a voltage which is lower than the power supply voltage V_{DD} and higher than the ground voltage V_{SS}. In this embodiment, the intermediate power supply voltage V_{MH} is set to a voltage V_{DD}/2 which is a half of the power supply voltage V_{DD}. Note that, like the first embodiment, the input stage 11 according to the second embodiment operates by receiving the power supply voltage V_{DD} and the ground voltage V_{SS}. Second, the back gate is connected to the source in the NMOS transistor MN₉ in the floating current source in the output stage 12B, and is thus biased to the potential of the source. Note that the back gate of the PMOS transistor MP₉ according to this embodiment is biased to the power supply voltage V_{DD}. Third, the current source 25 and the NMOS transistors MN₁₁, MN₁₂ for generating the bias voltage BN3R in the bias circuit 2B operate by receiving the intermediate power supply voltage V_{MH} and the power supply voltage V_{DD}. Fourth, the back gate is connected to the source in the NMOS transistor MN₁₁ for generating the bias voltage BN3R, and is thus biased to the potential of the source. The rest of the configuration of the operational amplifier circuit 10B shown in FIG. 5 is the same as that of the operational amplifier circuit 10A shown in FIG. 3.

In the operational amplifier circuit 10B shown in FIG. 5, the operation of the output stage 12B by receiving the power supply voltage V_{DD} and the intermediate power supply voltage V_{MH} higher than the ground voltage V_{SS} is effective in reducing the power consumption of the output stage 12B. If the intermediate power supply voltage V_{MH} is the voltage V_{DD}/2 which is a half of the power supply voltage V_{DD}, the output stage 12B consumes only a half of the power which the output stage 12B would consume when being supplied with the ground voltage V_{SS}. Because the output stage 12B is supplied with the intermediate power supply voltage V_{MH} which is higher than the ground voltage V_{SS}, the voltage outputted from the output stage 12B is limited to a range of V_{MH}+0.2V to V_{DD}−0.2V. However, this limitation does not matter to some applications.

Another problem with the operation of the output stage 12B with the power supply voltage V_{DD} and the intermediate power supply voltage V_{MH} is difficulty in ensuring a voltage large enough to operate the floating current source (formed of the PMOS transistor MP₉ and the NMOS transistor MN₉) in the output stage 12B. The amplifier circuit 1B according to this embodiment avoids this problem by connecting the back gate of the NMOS transistor MN₉ to the source thereof.

While the operational amplifier circuit 10B shown in FIG. 5 is operating, a voltage V_{BN3R} between the gate of the NMOS transistor MN₉ receiving the bias voltage BN3R and the power supply line 17B through which the intermediate power supply voltage V_{Mh} is supplied is equal to the sum of a voltage between the gate and source of the NMOS transistor MN₁₀ and a voltage between the gate and source of the NMOS transistor MN₉. Thus, the voltage V_{BN3R} is expressed by the following formula:

V_{BN3R}=V_{GS(MN10)}+V_{GS(MN9)} Formula (7)

where V_{GS(MN10)} denotes the voltage between the gate and source of the NMOS transistor MN₁₀, and V_{GS(MN9)} denotes the voltage between the gate and source of the NMOS-transistor MN₉.

For this reason, the condition expressed with the following formula needs to be satisfied for operating the operational amplifier circuit 10B shown in FIG. 5.

V_{MH}+V_{BN3R}+V_{DS(sat)}<VDD Formula (8)

From Formula (8),

V_{BN3R}<(VDD−V_{MH})−V_{DS(sat)} Formula (8′)

is obtained.

Here, the voltage between the back gate and source of the NMOS transistor MN₉ is zero, because the back gate of the NMOS transistor MN₉ is connected to the source thereof. Specifically, the value representing the third term of Formula (3) is zero for the NMOS transistor MN₉. Accordingly, the voltage V_{GS(MN9)} between the gate and source of the NMOS transistor MN₉ is reduced. This makes it possible to satisfy the condition expressed with Formula (8′) even when the power supply voltage V_{DD} becomes lower. In other words, the operational amplifier circuit 10B can carry out its low-voltage operation.

In addition, for causing the bias circuit 2B to generate the bias voltage BN3R, the operational amplifier circuit 10B shown in FIG. 5 uses the power supply voltage V_{DD} and the intermediate power supply voltage V_{MH} which is higher than the ground voltage V_{SS}. In other words, the NMOS transistors MN₁₁, NM₁₂ and the current source 25 are connected between a power supply line 20 through which the power supply voltage V_{DD} is supplied and a power supply line 18B through which the intermediate power supply voltage V_{MH} is supplied. Thereby, the operational amplifier circuit 10B can efficiently reduce the power consumption of the circuit part formed of the NMOS transistors MN₁₁, MN₁₂ and the current source 25.

Here, the foregoing discussion is the case with the NMOS transistors MN₁₁, MN₁₂ as well. Specifically, when the power supply voltage V_{DD} becomes lower, it becomes difficult to operate the NMOS transistors MN₁₁, MN₁₂ and the current source 25. For this reason, the condition expressed with Formula (9) needs to be satisfied for operating the NMOS transistors MN₁₁, MN₁₂ and the current source 25:

V_{GS(MP11)}+V_{GS(MP12)}+V_{DS(sat)}<V_{DD}−V_{MH} Formula (9)

where V_{GS(MP11)} denotes the voltage between the gate and source of the NMOS transistor MN₁₁, and V_{GS(MP12)} denotes the voltage between the gate and source of the NMOS transistor MN₁₂. Because the back gate of the NMOS transistor MN₁₁ is connected to the source thereof, the value representing the third term of Formula (3) is zero for the NMOS transistor MN₁₁. Accordingly, the voltage V_{GS(MP11)} between the gate and source of the NMOS transistor MN₁₁ is reduced. This makes it possible to satisfy the condition expressed with Formula (9) even when the power supply voltage V_{DD} becomes lower (that is, even while the operational amplifier circuit 10B is operating with a lower voltage). In other words, the operational amplifier circuit 10B can carry out its low-voltage operation.

As described above, the operational amplifier circuit 10B according to this embodiment can reduce its power consumption by allowing the output stage 12B to operate by receiving the power supply voltage V_{DD} and the intermediate power supply voltage V_{MH} (which is higher than the ground voltage V_{SS}). In addition, the operational amplifier circuit 10B can carry out its low-voltage operation because the back gate is connected to the source in the NMOS transistor MN₉ in the output stage 12B. Furthermore, the operational amplifier circuit 10B can carry out low-voltage operation because the back gate is connected to the source in the NMOS transistor MN₁₁ used to generate the bias voltage BN3R.

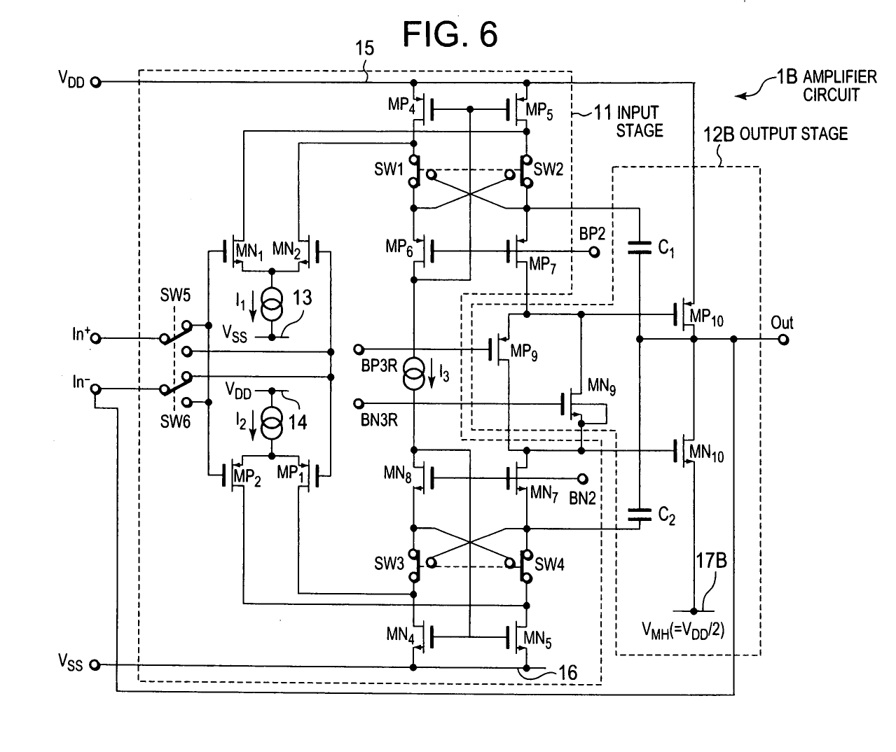

The configuration of the operational amplifier circuit 10B shown in FIG. 5 is also likely to increase an offset voltage in some cases. For this reason, the offset voltage needs to be dealt with depending on cases. Like the first embodiment, this embodiment can deal with the problem with the offset voltage by adding an offset cancellation circuit to the amplifier circuit 1B. FIG. 6 is a circuit diagram showing the configuration of the amplifier circuit 1B to which the offset cancellation circuit is added.

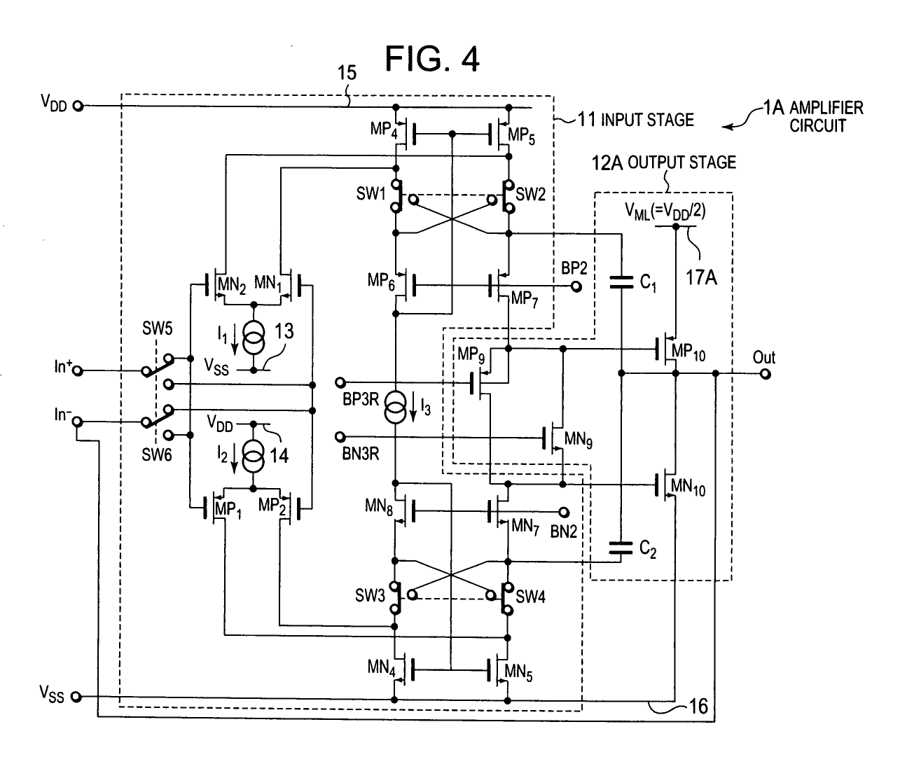

The configuration of the amplifier circuit 1B shown in FIG. 6 is obtained by inserting make/break switches SW1 to SW6 in the amplifier circuit 1B shown in FIG. 4. The amplifier circuit 1B shown in FIG. 6 is the same as the amplifier circuit 1A shown in FIG. 4 in terms of the connection relationship among the switches SW1 to SW6 and the other MOS transistors;

Specifically, the switch SW1 is inserted between the drain of the PMOS transistor MP₄ and the sources of the PMOS transistors of MP₆, MP₇, as well as the switch SW2 is inserted between the drain of the PMOS transistor MP₅ and the sources of the PMOS transistors MP₆, MP₇. The common terminal of the switch SW1 is connected to the drain of the PMOS transistor MP₄, the make terminal of the switch SW1 is connected to the source of the PMOS transistor MP₇, and the break terminal of the switch SW1 is connected to the source of the PMOS transistor MP₆. On the other hand, the common terminal of the switch SW2 is connected to the drain of the PMOS transistor MP₅, the make terminal of the switch SW2 is connected to the source of the PMOS transistor MP₆, and the break terminal of the switch SW2 is connected to the source of the PMOS transistor MP₇.

Similarly, the switch SW3 is inserted between the drain of the NMOS transistor MN₄ and the sources of the NMOS transistors MN₆, MN₇, as well as the switch SW4 is inserted between the drain of the NMOS transistor MN₅ and the sources of the NMOS transistors MN₆, MN₇. The common terminal of the switch SW3 is connected to the drain of the NMOS transistor MN₄, the make terminal of the switch SW3 is connected to the source of the NMOS transistor MN₇, and the break terminal of the switch SW3 is connected to the source of the NMOS transistor MN₆. On the other hand, the common terminal of the switch SW4 is connected to the drain of the NMOS transistor MN₅, the make terminal of the switch SW4 is connected to the source of the NMOS transistor MN₆, and the break terminal of the switch SW4 is connected to the source of the NMOS transistor MN₇.

Furthermore, the switch SW5 is inserted between the non-inverting input terminal In⁺ and the two differential transistor pairs (i.e., the paired NMOS transistors MN₁, MN₂ and the paired PMOS transistors MP₁, MP₂) of the input stage 11, whereas the switch SW6 is inserted between the inverting input terminal In⁻ and the two differential transistor pairs of the input stage 11. The common terminal of the switch SW5 is connected to the non-inverting input terminal In⁺, the make terminal of the switch SW5 is connected to the gates of the NMOS transistor MN₁ and the PMOS transistor MP₁, and the break terminal of the switch SW5 is connected to the gates of the NMOS transistor MN₂ and the PMOS transistor MP₂. On the other hand, the common terminal of the switch SW6 is connected to the inverting input terminal In⁻, the make terminal of the switch SW6 is connected to the gates of the NMOS transistor MN₂ and the PMOS transistor MP₂, and the break terminal of the switch SW6 is connected to the gates of the NMOS transistor MN₁ and the PMOS transistor MP₁.

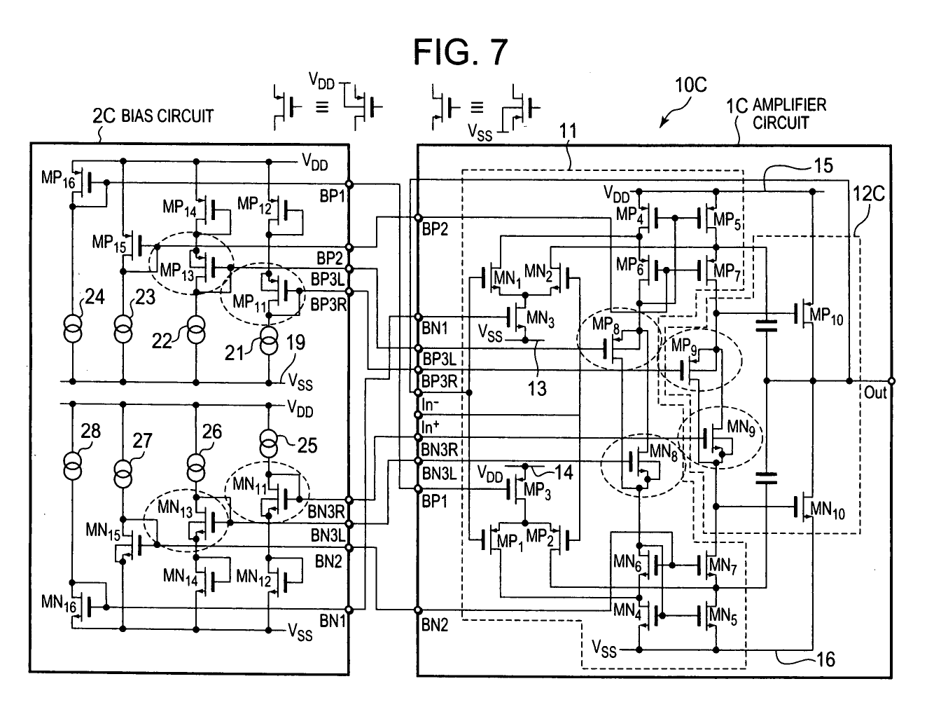

All the switches SW1 to SW6 operate in linkage with one another. The amplifier circuit 1B can select the make condition in which the common and make terminals of each of the switches SW1 to SW6 are connected together, and the break condition in which the common and break terminals of each of the switches SW1 to SW6 are connected together. Like the amplifier circuit 1A shown in FIG. 4, the amplifier circuit 1B shown in FIG. 7 switches the switches SW1 to SW6 together between the two conditions at appropriate intervals, and thus makes the time-average offset voltage equal to zero. Thereby, the problem with the offset voltage can be substantially solved.

### Third Embodiment

FIG. 7 is a circuit diagram showing the configuration of an operational amplifier circuit 10C according to a third embodiment of the present invention. The configuration of the operational amplifier circuit 10C shown in FIG. 7 is similar to that of the operational amplifier circuit 10A shown in FIG. 3, and the two operational amplifier circuits are different from each other in terms of the following points.

First, the operational amplifier circuit 10C shown in FIG. 7 does not use the intermediate power supply voltage which is higher than the ground voltage V_{SS} and lower than the power supply voltage V_{DD}. In other words, an output stage 12C of an amplifier circuit 1C operates by receiving the power supply voltage V_{DD} and the ground voltage V_{SS}. Specifically, the source of the PMOS transistor MP₁₀ is connected to the power supply line 15 through which the power supply voltage V_{DD} is supplied, whereas the source of the NMOS transistor MN₁₀ is connected to the ground line 16 through which the ground voltage V_{SS} is supplied. In addition, all the MOS transistors and current sources in a bias circuit 2C operate by receiving the power supply voltage V_{DD} and the ground voltage V_{SS}.

Second, the back gates are connected to the sources in the PMOS transistor MP₉ and the NMOS transistor MN₉ constituting the floating current source in the output stage 12C, and the back gates are connected to the sources in the PMOS transistor MP₈ and the NMOS transistor MN₈ constituting the floating current source in an input stage 11C, respectively. In other words, the back gates are all biased to the potentials of the sources in the PMOS transistor MP₉, the NMOS transistor MN₉, the PMOS transistor MP₈ and the NMOS transistor MN₈, respectively. This is effective in enabling the operational amplifier circuit 10C shown in FIG. 7 to carry out its lower-voltage operation. The voltage between the gate and source of each of the PMOS transistors MP₈, MP₉ and the NMOS transistors MN₈, MN₉ is reduced because the back gates of these MOS transistors are connected to the sources thereof, respectively. This effectively reduces the voltage levels of the bias voltages BP3L, BP3R, BN3L, BN3R respectively supplied to the PMOS transistors MP₈, MP₉ and the NMOS transistors MN₈, MN₉. This makes it possible for the operational amplifier circuit 10C to operate with a lower power supply voltage V_{DD}.

Third, the back gates are connected to the sources in the PMOS transistors MP₁₁, MP₁₃ and the NMOS transistors MN₁₁, MN₁₃ in the bias circuit 2C, respectively; In other words, the back gates are all biased to the potentials of the sources in the PMOS transistors MP₁₁, MP₁₃ and the NMOS transistors MN₁₁, MN₁₃, respectively. This is effective in enabling the operational amplifier circuit 10C shown in FIG. 7 to carry out its low-voltage operation. The voltage between the gate and source of each of the PMOS transistors MP₁₁, MP₁₃ and the NMOS transistors MN₁₁, MN₁₃ is reduced because the back gates of these MOS transistors are connected to the sources thereof, respectively. This makes it possible to operate the PMOS transistors MP₁₁, to MP₁₄, the NMOS transistors MN₁₁, to MN₁₄, and the current sources 21, 22, 25, 26 even when the power supply voltage V_{DD} becomes lower. In other words, this makes it possible for the bias circuit 2C to operate with the lower voltage.

As described above, this embodiment enables the amplifier circuit 1C to carry out its low-voltage operation by connecting the back gates of the MOS transistors to the sources thereof, respectively, the MOS transistors constituting the floating current source in each of the input stage 11C and the output stage 12C. Furthermore, this embodiment enables the bias circuit 2C to carry out its low-voltage operation by connecting the back gates of the MOS transistors (the PMOS transistors MP₁₁, MP₁₃, and the NMOS transistors MN₁₁, NM₁₃) to the sources thereof, the MOS transistors constituting the circuit parts for supplying these current sources with the bias voltages.

### (Application to Liquid Crystal Display Unit)

The above-described operational amplifier circuits are suitable to be used as amplifiers for a driver integrated circuit (IC) for driving a liquid crystal display panel or any other type of display panel. One of their effective uses is a data line driver for driving a data line of a liquid crystal display panel. In recent years, a data line driver of a type capable of making outputs for even more than 1000 channels has emerged for liquid crystal display panels. More than 1000 operational amplifier circuits connected as voltage followers are installed in such a data line driver. Because the number of outputs made from a data line driver is that large, the power consumed by the data line driver as a chip is accordingly large. As a result, the temperature of the chip is likely to rise to approximately 150° C. which is an operating limit on a silicon semiconductor device. On the contrary, the use of the above-described operational amplifier circuits (particularly, the operational amplifier circuits according to the first and second embodiments) makes it possible to drastically reduce the power consumption of the data line driver.

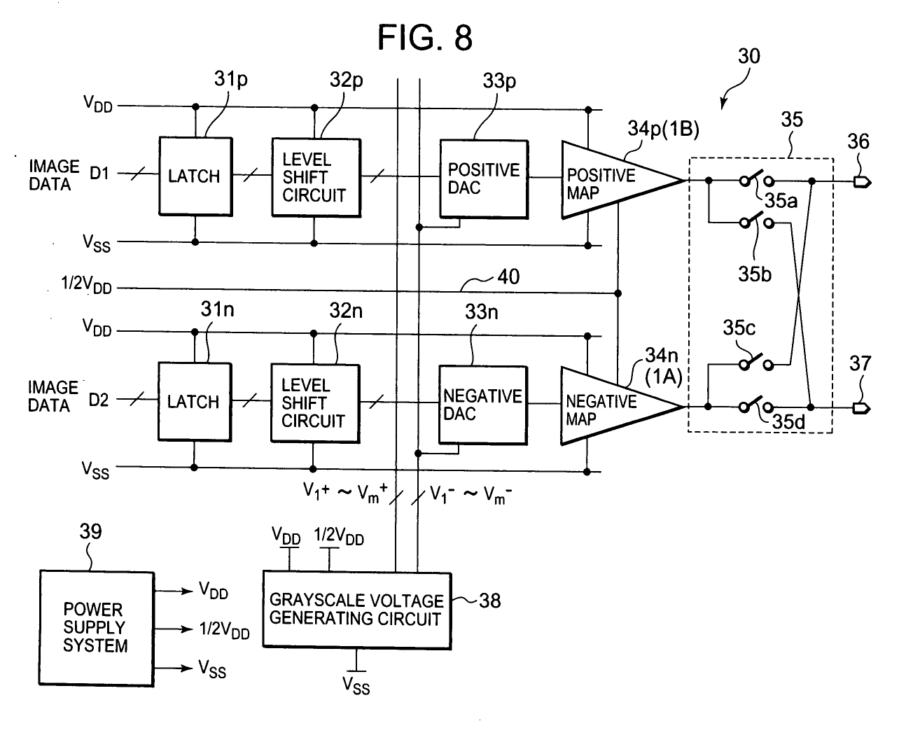

FIG. 8 is a block diagram showing the configuration of a liquid crystal display panel driving apparatus 30 according to an embodiment. The liquid crystal display panel driving apparatus 30 includes: latches 31p, 31n; level shift circuits 32p, 32n; a positive-side D/A (digital-to-analog) converter (DAC) 33p and a negative-side DAC 33n; a positive-side amplifier 34p and a negative-side amplifier 34n; a switch circuit 35; output terminals 36, 37; a grayscale voltage generating circuit 38; and a power supply system 39. The liquid crystal display panel driving apparatus 30 is configured to output, from the output terminals 36, 37, driving voltages for driving a data line of a liquid crystal display panel in response to sets of image data D1, D2 supplied to the latches 31p, 31n, respectively. Here, the sets of image data D1, D2 indicate the grayscale of a corresponding pixel to be driven. The voltage levels of the driving voltages outputted from the output terminals 36, 37 are determined depending on the image data D1, D2.

The latch 31p, the level shift circuit 32p, the positive-side D/A converter (DAC) 33p and the positive-side amplifier 34p are circuits for generating the driving voltage which is higher than a common voltage V_{COM} and lower than the power supply voltage V_{DD} in response to the image data D1. In this embodiment, the common voltage V_{COM} is the voltage V_{DD}/2 which is a half of the power supply voltage V_{DD}. For this reason, the driving voltage outputted from the positive-side amplifier 34p is higher than the voltage V_{DD}/2 and lower than the power supply voltage V_{DD}.

Specifically, the latch 31p latches the image data D1, and transmits the latched image data D1 to the positive-side DAC 33p through the level shift circuit 32p. The level shift circuit 32p matches the level of the output from the latch 31p to the level of the input into the positive-side DAC 33p by shifting the levels. The positive-side DAC 33p converts the resultant image data D1 from digital to analog. More specifically, the positive-side DAC 33p receives grayscale voltages V₁⁺ to Vₘ⁺ from the grayscale voltage generating circuit 38, and selects a grayscale voltage corresponding to the image data D1 out of the received grayscale voltages V₁⁺ to Vₘ⁺. Thereby, the positive-side DAC 33p supplies the thus-selected grayscale voltage to the positive-side amplifier 34p. Here, all the grayscale voltages V₁⁺ to Vₘ⁺ are higher than the voltage V_{DD}/2 and lower than the power supply voltage V_{DD}. The positive-side amplifier 34p operates as a voltage follower, and thus outputs a driving voltage having the same voltage level as the grayscale voltage received from the positive-side DAC 33p. As described later, the positive-side amplifier 34p operates by receiving the intermediate power supply voltage V_{DD}/2 in addition to the power supply voltage V_{DD} and the ground voltage V_{SS}.

On the other hand, the latch 31n, the level shift circuit 32n, the negative-side DAC 33n and the negative-side amplifier 34n are circuits for generating the driving voltage which is higher than the ground voltage V_{SS} and lower than the common voltage V_{COM} in response to the image data D2. In this embodiment, because the common voltage V_{COM} is the voltage V_{DD}/2 which is a half of the power supply voltage V_{DD}, the driving voltage outputted from the negative-side amplifier 34n is accordingly higher than the ground voltage V_{SS} and lower than the voltage V_{DD}/2.

Specifically, the latch 31n latches the image data D2, and transmits the latched image data D2 to the negative-side DAC 33n through the level shift circuit 32n. The level shift circuit 32n matches the level of the output from the latch 31n and the level of the input into the negative-side DAC 33n by shifting the levels. The negative-side DAC 33n converts the resultant image data D2 from digital to analog. More specifically, the negative-side DAC 33n receives grayscale voltages V₁⁻ to Vₘ⁻ from the grayscale voltage generating circuit 38, and selects a grayscale voltage corresponding to the image data D2 out of the received grayscale voltages V₁⁻ to Vₘ⁻. Thereby, the negative-side DAC 33n supplies the thus-selected grayscale voltage to the negative-side amplifier 34n. Here, all the grayscale voltages V₁⁻ to Vₘ⁻, are higher than the voltage V_{DD}/2 and lower than the power supply voltage V_{DD}. The negative-side amplifier 34n operates as a voltage follower, and thus outputs the driving voltage having the same voltage level as the grayscale voltage received from the negative-side DAC 33n. As described later, the negative-side amplifier 34n operates by receiving the intermediate power supply voltage V_{DD}/2 in addition to the power supply voltage V_{DD} and the ground voltage V_{SS}.

The switch circuit 35 is a circuit for switching the connection of the positive-side amplifier 34p between the output terminal 36 and the output terminal 37, as well as the connection of the negative-side amplifier 34n between the output terminal 37 and the output terminal 36. In a case where the driving voltage which is higher than the common voltage V_{COM} and lower than the power supply voltage V_{DD} is outputted from the output terminal 36 whereas the driving voltage which is higher than the ground voltage V_{SS} and lower than the common voltage V_{COM} is outputted from the output terminal 37, the switch circuit 35 sets the switches 35a, 35d to ON, and sets the switches 35b, 35c to OFF. Thereby, the positive-side amplifier 34p is connected to the output terminal 36, and the negative-side amplifier 34n is connected to the output terminal 37. Consequently, the driving voltage which is higher than the common voltage V_{COM} and lower than the power supply voltage V_{DD} is outputted from the output terminal 36, and the driving voltage which is higher than the ground voltage V_{SS} and lower than the common voltage V_{COM} is outputted from the output terminal 37. On the other hand, in a case where the driving voltage which is higher than the ground voltage V_{SS} and lower than the common voltage V_{COM} is outputted from the output terminal 36 whereas the driving voltage which is higher than the common voltage V_{COM} and lower than the power supply voltage V_{DD} is outputted from the output terminal 37, the switch circuit 35 sets the switches 35b, 35c to ON, and sets the switches 35a, 35d to OFF.

The grayscale voltage generating circuit 38 supplies the grayscale voltages V₁⁺ to Vₘ⁺ to the positive-side DAC 33p, and the grayscale voltages V₁⁻ to Vₘ⁻, to the negative-side DAC 33n.

The power supply system 39 generates the power supply voltage V_{DD}, the intermediate power supply voltage V_{DD}/2 and the ground voltage V_{SS}, and supplies these voltages to the circuit parts in the liquid crystal display panel driving apparatus 30.

The liquid crystal display panel driving apparatus 30 shown in FIG. 8 uses the operational amplifier circuit 10B according to the second embodiment (the operational amplifier circuit shown in FIGS. 5 and 6) as the positive-side amplifier 34p, and the operational amplifier circuit 10A according to the first embodiment (the operational amplifier circuit shown in FIGS. 3 and 4) as the negative-side amplifier 34n. At this time, the intermediate power supply voltage V_{ML} supplied to the operational amplifier circuit 10A used as the negative-side amplifier 34n and the intermediate power supply voltage V_{MH} supplied to the operational amplifier circuit 10B used as the positive-side amplifier 34p are both set to the voltage V_{DD}/2 which is a half of the power supply voltage V_{DD}. This makes it possible to supply both the positive-side amplifier 34p and the negative-side amplifier 34n with the intermediate power supply voltage through a single power supply line 40.

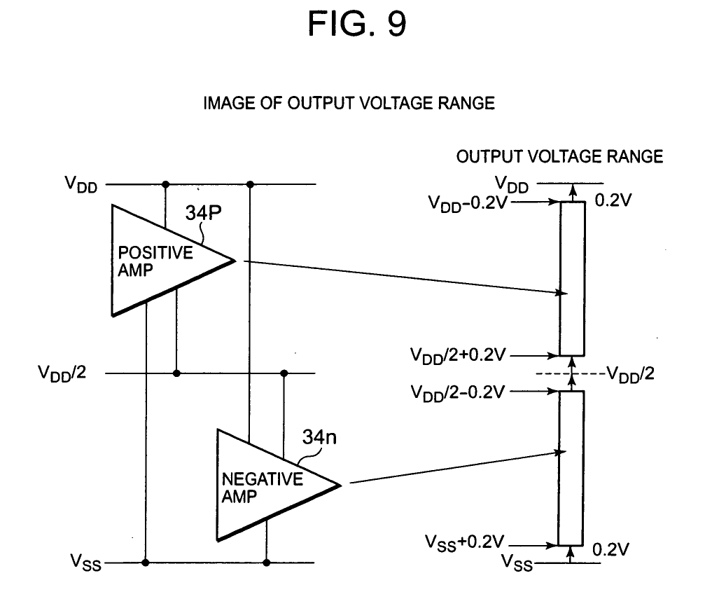

FIG. 9 is a conceptual diagram showing ranges of the output voltages outputted from the liquid crystal display panel driving apparatus 30 shown in FIG. 8. With regard to the operational amplifier circuit 10B used as the positive-side amplifier 34p, its input stage 11 operates by receiving the power supply voltage V_{DD} and the ground voltage V_{SS}, whereas its output stage 12B operates by receiving the power supply voltage V_{DD} and the intermediate power supply voltage V_{DD}/2. In this case, a range of the output voltage outputted from the positive-side amplifier 34p is V_{DD}/2+0.2 (V) to V_{DD}−0.2 (V). On the other hand, with regard to the operational amplifier circuit 10A used as the negative-side amplifier 34n, its input stage 11 operates by receiving the power supply voltage V_{DD} and the ground voltage V_{SS}, whereas its output stage 12A operates by receiving the ground voltage V_{SS} and the intermediate power supply voltage V_{DD}/2. In this case, a range of the output voltage outputted from the negative-side amplifier 34n is V_{SS}+0.2 (V) to V_{DD}/2−0.2 (V). The configuration shown in FIG. 8 cannot output a driving voltage in a range of V_{DD}/2−0.2 (V) to V_{DD}/2+0.2 (V). However, this does not matter to the driving of the liquid crystal display panel. Instead, the use of the operational amplifier circuits 10A, 10B for driving the liquid crystal display panel has an advantage in reducing the power consumption of the liquid crystal display panel driving apparatus, as described above.

For the purpose of further reducing the power consumption of the liquid crystal display panel driving apparatus 30, it is desirable that the above-described operational amplifier circuits be used as γ amplifiers in the grayscale voltage generating circuit 38 for generating the grayscale voltages V₁⁺ to Vₘ⁺ and the grayscale voltages V₁⁻ to Vₘ⁻. Here, the 9 γ amplifiers are amplifiers for supplying-bias voltages to a ladder resistor used to generate the grayscale voltages V₁⁺ to Vₘ⁺ and the grayscale voltages V₁⁻ to Vₘ⁻, for the purpose of allowing the grayscale voltages V₁⁺ to Vₘ⁺ and the grayscale voltages V₁⁻ to Vₘ^{- to be generated in accordance with a desired gamma curve.}

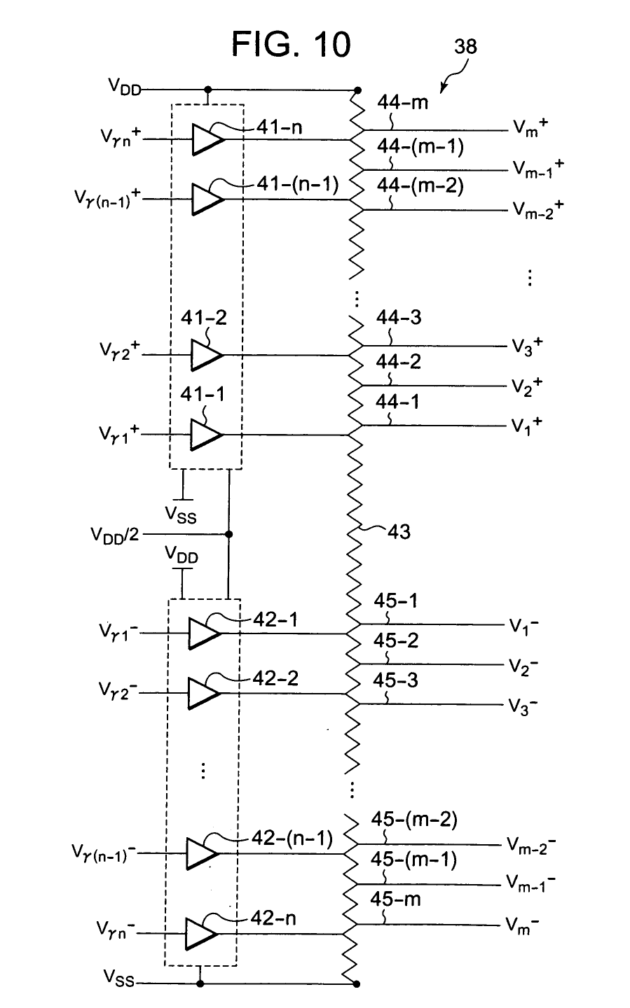

FIG. 10 is a circuit diagram showing an example of the grayscale voltage generating circuit 38 using the operational amplifier circuits 10A and 10B according to the respective first and second embodiments as its γ amplifiers. The grayscale voltage generating circuit 38 shown in FIG. 10 includes: positive-side γ amplifiers 41-1 to 41-n, negative-side γ amplifiers 42-1 to 42-n, and a ladder resistor 43. The positive-side γ amplifiers 41-1 to 41-n supply the ladder resistor 43 with bias voltages which are higher than the intermediate power supply voltage V_{DD}/2 and lower than the power supply voltage V_{DD}, respectively. The negative-side γ amplifiers 42-1 to 42-n supply the ladder resistor 43 with bias voltages which are higher than the ground voltage V_{SS} and lower than the intermediate power supply voltage V_{DD}/2, respectively. The ladder resistor 43 is connected between a power supply line through which the power supply voltage V_{DD} is supplied and a ground line through which the ground voltage V_{SS} is supplied. Thus, the ladder resistor 43 generates the grayscale voltages V₁⁺ to Vₘ⁺ and the grayscale voltages V₁⁻ to Vₘ⁻ through voltage division. The grayscale voltages V₁⁺ to Vₘ⁺ thus generated are supplied to the positive-side amplifier 34p through signal lines 44-1 to 44-m, whereas the grayscale voltages V₁⁻ to Vₘ⁻ thus generated are supplied to the negative-side amplifier 34n through signal lines 45-1 to 45-m.

In the grayscale voltage generating circuit-38 shown in FIG. 11, the operational amplifier circuit 10B according to the first embodiment is used as each of the positive-side γ amplifiers 41-1 to 41-n. The use of the operational amplifier circuit 10B whose output stage 12B operates by receiving the power supply voltage V_{DD} and the intermediate power supply voltage V_{DD}/2 is effective in reducing the power consumption. Similarly, the operational amplifier circuit 10A according to the second embodiment is used as each of the negative-side γ amplifiers 42-1 to 42-n. The use of the operational amplifier 10A whose output stage 12A operates by receiving the ground voltage V_{SS} and the intermediate power supply voltage V_{DD}/2 is effective in reducing the power consumption.

The foregoing descriptions have been provided for the specific embodiments of the present invention. However, note that the present invention can be carried out as various modifications, and that the present invention shall not be construed as being limited to the above-described embodiments. In particular, it should be noted that the present invention can be applied to a display panel driving apparatus for driving data lines of a display panel other than the liquid crystal display panel, although the foregoing descriptions have been provided for the embodiment in which the operational amplifier circuits are applied to the liquid crystal display panel driving apparatus for driving the liquid crystal display panel. Furthermore, the operational amplifier circuits according to the present invention are applicable to other various uses requiring an operation with a lower voltage and with less power consumption.

What is claimed is:

1. An operational amplifier circuit comprising:
an input stage which generates a first internal current corresponding to a potential difference between an inverting input terminal and a non-inverting input terminal; and
an output stage which drives an output terminal corresponding to the first internal current, wherein
the output stage includes:
a first floating current source through which the first internal current flows;
a first output transistor which drives the output terminal corresponding to a potential of a first terminal of the first floating current source; and
a second output transistor which drives the output terminal corresponding to a potential of a second terminal of the first floating current source,
the first floating current source includes:
a first PMOS transistor whose source and drain are respectively connected to the first and second terminals; and
a first NMOS transistor whose drain and source are respectively connected to the first and second terminals, and
in at least one of the first PMOS transistor and the first NMOS transistor, a back gate is connected to a source.

2. The operational amplifier circuit according to claim 1, wherein
the input stage operates by receiving a power supply voltage and a ground voltage,
the first output transistor is connected between the output terminal and a power supply line through which an intermediate power supply voltage is supplied, the intermediate power supply voltage being lower than the power supply voltage and higher than the ground voltage,
the second output transistor is connected between the output terminal and a ground line through which the ground voltage is supplied, and
the back gate of the first PMOS transistor is connected to the source thereof.

3. The operational amplifier circuit according to claim 2, further comprising a bias circuit which supplies a bias voltage to a gate of the first PMOS transistor, wherein
the bias circuit includes a diode-connected PMOS transistor and a current source which are connected together in series between a power supply line through which the intermediate power supply voltage is supplied, and a ground line through which the ground voltage is supplied,
the bias voltage is outputted from a gate of the diode-connected PMOS transistor to the gate of the first PMOS transistor, and
a back gate of the diode-connected PMOS transistor is connected to a source thereof.

4. The operational amplifier circuit according to claim 1, wherein
the input stage operates by receiving a power supply voltage and a ground voltage,
the first output transistor is connected between the output terminal and a power supply line through which the power supply voltage is supplied,
the second output transistor is connected between the output terminal and a power supply line through which an intermediate power supply voltage is supplied, the intermediate power supply voltage being lower than the power supply voltage and higher than the ground voltage, and
a back gate of the first NMOS transistor is connected to the source thereof.

5. The operational amplifier circuit according to claim 4, further comprising a bias circuit which supplies a bias voltage to a gate of the first NMOS transistor, wherein
the bias circuit includes a diode-connected NMOS transistor and a current source that are connected together in series between a first power supply line through which the power supply voltage is supplied, and a second power supply line through which the intermediate power supply voltage is supplied,
the bias voltage is outputted from a gate of the diode-connected NMOS transistor to the gate of the first NMOS transistor, and
a back gate of the diode-connected NMOS transistor is connected to a source thereof.

6. The operational amplifier circuit according to claim 2, wherein
the intermediate power supply voltage is a half of the power supply voltage.

7. The operational amplifier circuit according to claim 1, wherein
the input stage includes a second floating current source connected between a third terminal and a fourth terminal,
the input stage is configured so that a second internal current flows through the second floating current source, the second internal current corresponding to a potential difference between the inverting input terminal and the non-inverting input terminal,
the second floating current source includes:
a second PMOS transistor whose source and drain are respectively connected to the third and fourth terminals; and
a second NMOS transistor whose drain and source are respectively connected to the third and fourth terminals, and
in each of the first PMOS transistor, the first NMOS transistor, the second PMOS transistor and the second NMOS transistor, a back gate is connected to the source.

8. The operational amplifier circuit according to claim 2, wherein
the input stage includes:
a first differential transistor pair which includes a third NMOS transistor and a fourth NMOS transistor; and
a second differential transistor pair which includes a third PMOS transistor whose gate is connected to a gate of the third NMOS transistor, and a fourth PMOS transistor whose gate is connected to a gate of the fourth NMOS transistor,
the gates of the third NMOS transistor and the third PMOS transistor are connected to one of the inverting input terminal and the non-inverting input terminal, and
the gates of the fourth NMOS transistor and the fourth PMOS transistor are connected to the other of the inverting input terminal and the non-inverting input terminal.

9. The operational amplifier circuit according to claim 8, wherein
the input stage further includes:
a first switch which performs switching between a connection of the inverting input terminal with the gates of the third NMOS transistor and the third PMOS transistor, and a connection of the inverting input terminal with the gates of the fourth NMOS transistor and the fourth PMOS transistor; and
a second switch which performs switching between a connection of the non-inverting input terminal with the gates of the third NMOS transistor and the third PMOS transistor, and a connection of the non-inverting input terminal with the gates of the fourth NMOS transistor and the fourth PMOS transistor.

10. The operational amplifier circuit according to claim 8, further comprising a first cascode current mirror which is connected to the first differential transistor pair and used to supply the first internal current to the first floating current source, wherein
the first cascode current mirror includes:
fifth and sixth PMOS transistors whose gates are applied with a common bias voltage;
seventh and eighth PMOS transistors whose gates are commonly connected to a drain of the fifth PMOS transistor, the seventh and eighth PMOS transistors functioning as an active load;
a third switch which performs switching between a connection of a drain of the seventh PMOS transistor with a source of the fifth PMOS transistor, and a connection of the drain of the seventh PMOS transistor with a source of the sixth PMOS transistor; and
a fourth switch which performs switching between a connection of a drain of the eighth PMOS transistor with the source of the fifth PMOS transistor, and a connection of the drain of the eighth PMOS transistor with the source of the sixth PMOS transistor.

11. The operational amplifier circuit according to claim 8, further comprising a second cascode current mirror which is connected to the second differential transistor pair and receives the first internal current from the first floating current source, wherein
the second cascode current mirror includes:
fifth and sixth NMOS transistors whose gates are applied with a common bias voltage;
seventh and eighth NMOS transistors whose gates are commonly connected to the a drain of the fifth NMOS transistor, the seventh and eighth NMOS transistors functioning as an active load;
a fifth switch which performs switching between a connection of a drain of the seventh NMOS transistor with a source of the fifth NMOS transistor, and a connection of the drain of the seventh NMOS transistor with a source of the sixth NMOS transistor; and
a sixth switch which performs switching between a connection of a drain of the eighth NMOS transistor with the source of the fifth NMOS transistor, and a connection of the drain of the eighth NMOS transistor with the source of the sixth NMOS transistor.

12. A display panel driving apparatus for generating a driving voltage for driving a display panel, the apparatus comprising:
a positive-side amplifier which generates a first driving voltage in a range between a power supply voltage and an intermediate power supply voltage that is a half of the power supply voltage; and
a negative-side amplifier which generates a second driving voltage in a range between a ground voltage and the intermediate power supply voltage, wherein
each of the positive-side amplifier and the negative-side amplifier includes:
an input stage which generates an internal current corresponding to a potential difference between an input terminal and an output terminal; and
an output stage which outputs any one of the first and second driving voltages from the output terminal corresponding to the internal current,
the output stage includes:
a floating current source through which the internal current flows;
a first output transistor which drives the output terminal corresponding to a potential of a first terminal of the floating current source; and
a second output transistor which drives the output terminal corresponding to a potential of a second terminal of the floating current source,
the floating current source includes:
a PMOS transistor whose source and drain are respectively connected to the first and second terminals; and
an NMOS transistor whose drain and source are respectively connected to the first and second terminals,
in the PMOS transistor in the floating current source in the output stage of the positive-side amplifier, a back gate is connected to the source, and
in the NMOS transistor in the floating current source in the output stage of the negative-side amplifier, a back gate is connected to the source.

13. The display panel driving apparatus according to claim 12, wherein
the first output transistor of the positive-side amplifier is connected between a power supply line through which the intermediate power supply voltage is supplied and the output terminal, and
the second output transistor of the positive-side amplifier is connected between the output terminal and a ground line through which the ground voltage is supplied.

14. The display panel driving apparatus according to claim 12, wherein
the first output transistor of the negative-side amplifier is connected between the output terminal and a power supply line through which the power supply voltage is supplied, and
the second output transistor of the negative-side amplifier is connected between the output terminal and a power supply line through which the intermediate power supply voltage is supplied.

15. A display panel driving apparatus for generating a driving voltage for driving a display panel, the apparatus comprising:
a grayscale voltage supplying circuit which supplies a plurality of grayscale voltages;
a D/A converter which selects one of the plurality of grayscale voltages depending on image data; and
an amplifier which generates a driving voltage corresponding to the selected grayscale voltage, wherein
the grayscale voltage supplying circuit includes:
a positive-side γ amplifier which generates a positive-side bias voltage in a range between a power supply voltage and an intermediate power supply voltage that is a half of the power supply voltage;
a negative-side γ amplifier which generates a negative-side bias voltage in a range between the intermediate power supply voltage and a ground voltage; and
a ladder resistor which generates the grayscale voltages through voltage division upon receipt of the positive-side bias voltage and the negative-side bias voltage,
each of the positive-side γ amplifier and the negative-side γ amplifier includes:
an input stage which generates an internal current corresponding to a potential difference between an input terminal and an output terminal; and
an output stage which outputs any one of the positive-side bias voltage and the negative-side bias voltage from the output terminal in response to the internal current,
the output stage includes:
a floating current source through which the internal current flows;
a first output transistor which drives the output terminal corresponding to a potential of a first terminal of the floating current source; and
a second output transistor which drives the output terminal corresponding to a potential of a second terminal of the floating current source,
the floating current source includes:
a PMOS transistor whose source and drain are respectively connected to the first and second terminals; and
an NMOS transistor whose drain and source are respectively connected to the first and second terminals,
in the PMOS transistor in the floating current source in the output stage of the positive-side γ amplifier, a back gate is connected to the source, and
in the NMOS transistor in the floating current source in the output stage of the negative-side γ amplifier, a back gate is connected to the source.

16. The display panel driving apparatus according to claim 15, wherein
the first output transistor of the positive-side γ amplifier is connected between a power supply line through which the intermediate power supply voltage is supplied and the output terminal, and
the second output transistor of the positive-side γ amplifier is connected between the output terminal and a ground line through which the ground voltage is supplied.

17. The display panel driving apparatus according to claim 15, wherein
the first output transistor of the negative-side γ amplifier is connected between the output terminal and a power supply line through which the power supply voltage is supplied, and
the second output transistor of the negative-side γ amplifier is connected between the output terminal and a power supply line through which the intermediate power supply voltage is supplied.
